(19) United States
(12) Patent Application Publication
(10) Pub. No.: US 2022/0393059 A1
(43) Pub. Date: Dec. 8, 2022

(54) Component Composite and Method for Probing and Producing Components

(71) Applicant: OSRAM Opto Semiconductors GmbH, Regensburg (DE)

(72) Inventors: Korbinian Perzlmaier, Regensburg (DE); Peter Stauß, Regensburg (DE); Alexander F. Pfeuffer, Regensburg (DE); Christoph Klemp, Regensburg (DE); Kerstin Neveling, Pentling (DE); Andreas Biebersdorf, Regensburg (DE)

(21) Appl. No.: 17/771,368

(22) PCT Filed: Oct. 6, 2020
(86) PCT No.: PCT/EP2020/077918

§ 371 Date: Apr. 22, 2022

(30) Foreign Application Priority Data
Oct. 24, 2019 (DE) 10 2019 128 728.6

(51) Int. Cl. H01L 33/00; H01L 21/683

(52) U.S. Cl. CPC H01L 33/0095; H01L 21/6835; H01L 33/0093; H01L 33/30

(57) ABSTRACT

In an embodiment a component composite includes an auxiliary carrier, a plurality of components, a retaining structure and an electrically conductive sacrificial layer, wherein each of the components has a connection layer which faces the sacrificial layer and is electrically conductively connected to the sacrificial layer, wherein the sacrificial layer is arranged in vertical direction between the auxiliary carrier and the components, and wherein the sacrificial layer is to be removable and the components are mechanically connected to the auxiliary carrier only via the retaining structure in addition to the sacrificial layer.

This patent application is a national phase filing under section 371 of PCT/EP2020/077918, filed Oct. 6, 2020, which claims the priority of German patent application 102019128728.6, filed Oct. 24, 2019, each of which is incorporated herein by reference in its entirety.

### TECHNICAL FIELD

A component composite comprising of a plurality of components is disclosed. Furthermore, a method for probing the components, in particular on wafer level, and a method for producing the components are provided.

### BACKGROUND

Components, in particular LEDs, which are processed at wafer level and transferred directly, often do not have the opportunity to be electro-optically characterized before they are transferred and incorporated into end products. Thus, the electro-optical characterization of the components would only take place on an intermediate carrier or even during the application of the final product. This can result in high costs because, in the event of component failure, a highly refined, in particular finished end product must be reworked or even discarded.

### SUMMARY

Embodiments provide a component composite of components, wherein the components can be electro-optically characterized in particular already at wafer level. Further embodiments provide safe, simplified and cost-effective methods for probing and producing the components.

According to at least one embodiment of the component composite, it comprises an auxiliary carrier and a plurality of components arranged on the auxiliary carrier. In particular, a removable sacrificial layer is located in vertical direction between the carrier and the components. The sacrificial layer can be selectively removed from the component composite for instance by an etching step. Preferably, the sacrificial layer is formed to be electrically conductive. In particular, the sacrificial layer is electrically conductively connected to the components so that the components can already be electrically contacted on their back side at wafer level, i.e. already in the component composite, via the sacrificial layer.

A vertical direction is understood to be a direction which is in particular perpendicular to a main extension surface of the component composite or of the auxiliary carrier. A lateral direction is understood to be a direction which is in particular parallel to the main extension surface. The vertical direction and the lateral direction are orthogonal to each other.

The components can each have a front-side contact layer that is freely accessible in a top view of the auxiliary carrier. The components can be electrically contacted individually or in groups via the sacrificial layer and the front-side contact layers, as a result of which the components can already be tested in the component composite, for example with regard to functional efficiency, luminance, brightness and so on, and thus can be electro-optically characterized. The components that do not meet the specified requirements can already be marked or sorted out in the component composite.

According to at least one embodiment of the component composite, the components each comprise a semiconductor body. The semiconductor body may have a first semiconductor layer, a second semiconductor layer and an active zone, wherein the active zone is arranged in the vertical direction between the first semiconductor layer and the second semiconductor layer. In particular, the active zone is configured to generate or detect electromagnetic radiation, for example, in the infrared, visible, or ultraviolet spectral regions. The first semiconductor layer and the second semiconductor layer can be n-type and p-type, respectively, or vice versa. In particular, the semiconductor body has a diode structure. The component can be a semiconductor chip, such as a μLED.

The semiconductor body may be formed of a III/V compound semiconductor material. A III/V compound semiconductor material has an element from the third main group, such as B, Al, Ga, In, and an element from the fifth main group, such as N, P, As. In particular, the term “III/V compound semiconductor material” includes the group of binary, ternary or quaternary compounds containing at least one element from the third main group and at least one element from the fifth main group, for example nitride and phosphide compound semiconductors. Such a binary, ternary or quaternary compound may further include, for example, one or more dopants as well as additional constituents. For example, the semiconductor body is based on GaN, InGaN, AlGaN, InGaAlN, InGaP, InGaAlP, InGaAlAs, or on AlGaAs. Also, the semiconductor body may be formed of a II/VI compound semiconductor material.

In at least one embodiment of the component composite, it has an auxiliary carrier, a plurality of components and an electrically conductive sacrificial layer. The components each have a connection layer which faces the sacrificial layer and is electrically conductively connected to the sacrificial layer. The sacrificial layer is arranged in the vertical direction between the auxiliary carrier and the components. In addition, the sacrificial layer is formed to be removable.

In particular, the auxiliary carrier is an output wafer. The components on the auxiliary carrier can be electrically contacted via the sacrificial layer so that the components can be electrically probed individually or in groups in the component composite, i.e. already at wafer level, and thus can be characterized electro-optically. The components can thus be measured directly at wafer level. Possible fluctuations in production can be registered at an early stage so that faster feedback can be obtained for the development and production of the components. Process control in production is also improved, as the components can be checked electro-optically directly in the component composite in a non-destructive manner and without being removed.

If the sacrificial layer is removable, the components can be transferred individually or in groups from the auxiliary carrier to an intermediate carrier or to a target mounting surface of an end product after the removal of the sacrificial layer. With the aid of the electrically conductive sacrificial layer, the characterization of the components in particular does not require any complex additional processing steps that cause possible defects. For example, the components each have a front-side contact layer and a rear-side contact layer, with the front-side contact layer in particular being formed to be freely accessible and the rear-side contact layer being in electrical contact with the electrically conductive sacrificial layer. The components can thus be electrically contacted externally on the front side via the front-side contact layers and on the rear side via the sacrificial layer. The contact to the sacrificial layer can, for example, be guided laterally outwards to an edge of the auxiliary carrier, for example via a metallic reinforcement. The auxiliary carrier can be formed to be electrically insulating. However, if the auxiliary carrier is electrically conductive, electrical contact to the sacrificial layer can be made via the auxiliary carrier, for example via a rear surface or via a side surface of the auxiliary carrier.

According to at least one embodiment of the component composite, the components are laterally spaced from each other by separation trenches. In particular, the sacrificial layer is freely accessible in regions in the separation trenches. For example, the components or the semiconductor bodies of the components are of the same type. The semiconductor bodies of the components may be produced in a common method step. The separation trenches are, for example, mesa trenches, which are formed between the semiconductor bodies and separate the semiconductor bodies from one another, in particular completely.

According to at least one embodiment of the component composite, it has a retaining structure. In addition to the sacrificial layer, the components are in particular only mechanically connected to the auxiliary carrier via the retaining structure. The retaining structure is thus formed in particular in such a way that, after removal of the sacrificial layer, the components are mechanically connected to the auxiliary carrier only via the retaining structure.

The retaining structure has an anchoring layer which can be electrically insulating or electrically conductive. The anchoring layer can have retaining elements, which are formed in particular in the form of vertical projections of the anchoring layer. The retaining structure can also comprise a passivation layer which, in a plan view, covers the anchoring layer at least partially or, in particular, completely.

The retaining elements are preferably formed in such a way that they release the components, for example under mechanical load, so that the components are detachable from the auxiliary carrier and thus are transferable. The mechanical load can be a tensile force, shear force or compressive force exerted on the retaining structure and/or on the retaining elements. For example, the retaining elements are formed to break off, tear off, or detach from the associated component when the associated component is removed. If the component is formed to be detachable, the detachment of the retaining structure from the component takes place in particular at a common interface between the retaining structure and the component. This common interface can be an interface between two layers of different materials, for example between an insulating layer of the component and the passivation layer or the anchoring layer of the retaining structure.

According to at least one embodiment of the component composite, for each component, the retaining structure has a vertically projecting retaining element which is completely covered by the associated component when viewed from above onto the auxiliary carrier. Such retaining element may be referred to as retaining column. In lateral directions, the retaining column may be fully enclosed by the sacrificial layer. In particular, the retaining columns are arranged exclusively below the components, and along the vertical direction for instance exclusively between the components and the auxiliary carrier.

According to at least one embodiment of the component composite, for each component, the retaining structure has a vertically projecting retaining element which—in a plan view of the auxiliary carrier—is arranged in regions below the associated component and in regions to the side of the associated component. Such retaining element may be referred to as tether. It is possible that the tether is additionally arranged on one or on different side surfaces of the associated component.

According to at least one embodiment of the component composite, the components are formed to be transferable. The components can be formed to be transferable in that, after removal of the sacrificial layer, the components are mechanically connected to the auxiliary carrier exclusively via the retaining structure, as a result of which the components are formed to be detachable from the retaining structure and thus from the auxiliary carrier. A safe, orderly and cost-effective mass transfer of the components from a wafer to a target mounting surface can thus be achieved in a simple manner.

According to at least one embodiment of the component composite, the retaining structure has an anchoring layer that is electrically conductive and, in particular, formed from a metal or from an electrically conductive oxide. It is possible that the anchoring layer is formed of an electrically insulating material or of a benzocyclobutene-based material, such as of a benzocyclobutene-based polymer, or of an adhesive or plastic such as of an epoxy or a thermoset. Benzocyclobutene (BCB) is a polycyclic aromatic hydrocarbon compound composed of a combination of a benzene ring and a cyclobutane ring. The anchoring layer can be formed by rotational coating of the benzocyclobutene-based material.

According to at least one embodiment of the component composite, the retaining structure has an atomic layer deposition layer as a passivation layer disposed on the anchoring layer. Such a passivation layer can be formed by atomic layer deposition (ALD). Atomic layer deposition is a process of depositing extremely thin layers, up to atomic monolayers, on a starting material. For example, the passivation layer is an Al₂O₃ layer, a SiO₂ layer, a SiNx layer, a SiOxNy layer, or another dielectric layer.

Alternatively, the passivation layer can be a layer deposited via PVD (physical vapor deposition), such as evaporation or sputtering, or CVD (chemical vapor deposition). This layer may comprise a dielectric such as the layers mentioned above or a TCO (transparent conductive oxide) such as ITO (indium tin oxide) or ZnO. It is also possible that the passivation layer is a combination of ALD, PVD and/or CVD layers.

According to at least one embodiment of the component composite, the components each have a front-side contact layer and a rear-side contact layer. The front-side contact layer and the rear-side contact layer are assigned to different electrical polarities of the associated component. In particular, the rear-side contact layer is electrically conductively connected to the associated connection layer. Preferably, the front-side contact layer is freely accessible and can be electrically contacted via a needle or via an electron beam.

According to at least one embodiment of the component composite, the connection layer is in direct physical and electrical contact with the sacrificial layer. In other words, the connection layer is directly adjacent to the sacrificial layer, at least in places.

According to at least one embodiment of the component composite, the connection layer is covered by an electrically insulating boundary layer, wherein the boundary layer is arranged between the connection layer and the sacrificial layer. The boundary layer may have an opening in which the connection layer is in direct electrical contact with the sacrificial layer.

According to at least one embodiment of the component composite, in top view, the connection layer is completely covered by an electrically insulating boundary layer. The boundary layer is arranged in the vertical direction at least in regions between the connection layer and the sacrificial layer. The component composite has an electrically conductive bonding layer which in particular is laterally adjacent to the connection layer. Preferably, the electrically conductive bonding layer is at least partially non-covered by the boundary layer, as a result of which an electrical connection is established between the connection layer and the sacrificial layer.

According to at least one embodiment of the component composite, the connection layer is completely covered by an electrically conductive boundary layer, wherein the electrically conductive boundary layer is directly adjacent to the connection layer and directly adjacent to the sacrificial layer.

In particular, the electrically insulating or electrically conductive boundary layer forms a barrier layer that prevents or stops the exchange of particles, especially between the connection layer and the sacrificial layer. In this sense, the boundary layer forms a diffusion barrier layer.

According to at least one embodiment of the component composite, the sacrificial layer is a doped, in particular highly doped Si-, Ge- or Mo-layer. Depending on the assigned electrical polarity of the connection layer, the sacrificial layer can be p-type or n-type doped.

A highly doped sacrificial layer means in particular an electrically conductive layer which without the dopants, however, is hardly electrically conductive or not electrically conductive under normal conditions. It is possible that the doping is formed to be so high that the sacrificial layer is in the form of an alloy. For example, the dopants in the sacrificial layer have a content from 2% by weight to 20% by weight inclusive, such as from 4% by weight to 16% by weight inclusive, or from 2% by weight to 10% by weight inclusive. The dopants may be B, Al, Ga, In, P, As, Sb, Bi, or Li. For example, a Si layer is doped with Al or B. A Ge layer may be doped with Ga. If the sacrificial layer is a Si layer doped with Al, the amount of Al in the sacrificial layer may be from 2% by weight to 20% by weight, inclusive, or from 4% by weight to 16% by weight, inclusive. For example, the sacrificial layer is a layer with 94 wt % of Si and 6 wt % of Al or a layer with 84 wt % of Si and 16 wt % of Al.

According to at least one embodiment of the component composite, the connection layer is a metal layer. The connection layer may be formed of gold or of another metal, for instance another noble metal. Alternatively, it is possible that the connection layer is formed from a transparent electrically conductive material, for instance from a transparent electrically conductive oxide.

Transparent conductive oxides (TCO) include metal oxides such as zinc oxide, tin oxide, cadmium oxide, titanium oxide, indium oxide or indium tin oxide (ITO). In addition to binary metal oxygen compounds such as, for example, ZnO, SnO₂ or In₂O₃, ternary metal oxygen compounds such as, for example, Zn₂SnO₄, CdSnO₃, ZnSnO₃, MgIn₂O₄, GaInO₃, Zn₂In₂O₅ or In₄Sn₃O₁₂ or mixtures of different transparent, electrically conductive oxides also belong to the group of TCOs. Furthermore, the TCOs can be p- or n-doped.

According to at least one embodiment of the component composite, the components are optoelectronic components. In particular, the components are micro-LEDs. It is also possible that the component is a carrierless or packageless LED chip. In addition, the component may be a chip scale package (CSP) component with an integrated carrier structure, a triplet LED, a sensor chip, or a general optoelectronic component.

In at least one embodiment of a method for probing components, in particular at wafer level, a component composite, for example a component composite described herein, is provided. The auxiliary carrier may be a wafer substrate. In this case, the wafer substrate can be a growth substrate or different from a growth substrate on which the semiconductor bodies of the components are grown, in particular epitaxially grown. The components of the component composite are probed, in particular for operability, brightness, luminance, and so on, with the components being electrically contacted via the sacrificial layer while the components continue to be mechanically connected to the auxiliary carrier. By being probed, the components can be electro-optically characterized.

In at least one embodiment of a method for producing components, a component composite, for example a component composite described herein, is provided. The sacrificial layer is removed to form cavities between the auxiliary carrier and the components, wherein the components are mechanically connected to the auxiliary carrier in particular only via a retaining structure. The retaining structure can be arranged in the vertical direction between the auxiliary carrier and the components. The components are selectively separated from the auxiliary carrier by selectively separating or detaching the relevant components from the retaining structure. For example, using one stamp or several stamps, the components can be completely removed from the auxiliary carrier, either individually or in groups.

Alternatively or additionally, it is possible for the components or the component composite to be attached to a further auxiliary carrier, in particular before the sacrificial layer is removed. The further auxiliary carrier can be a film, in particular an elastic film. It is also possible for the further auxiliary carrier to be a printed circuit board, in particular one with electrical contact structures. The components are located in the vertical direction in particular between the auxiliary carrier and the further auxiliary carrier. In a further method step, the auxiliary carrier is removed so that the components are only mechanically supported by the further auxiliary carrier. The components can be separated and/or transferred from the further auxiliary carrier, in particular after being probed. After the sacrificial layer and the auxiliary carrier have been removed, the components are detachable from the further auxiliary carrier individually or in groups. The detachment of the components is carried out in particular by laser irradiation or mechanical stress. It is possible that the component composite is free of a retaining structure in this case. The components are arranged on the further auxiliary carrier and are not adjacent to in particular any retaining elements.

### BRIEF DESCRIPTION OF THE DRAWINGS

Further embodiments and further developments of the component composite or of the method for characterizing or for producing the components will be apparent from the exemplary embodiments explained below in connection with FIGS. 1A to 6.

FIGS. 1A and 1B show schematic illustrations of an exemplary embodiment of a component in a component composite in the presence and absence of a sacrificial layer;

FIG. 2A shows a schematic representation of an exemplary embodiment of a component composite in sectional view;

FIG. 2B show a schematic representation of a method step for detaching a component from a composite;

FIGS. 3A, 3B, 3C, 3D, 3E, 3F, 3G, 4A, 4B, 5A, 5B, 5C, 5D, 5E, and 5F show schematic representations of further exemplary embodiments of a component in a component composite; and

FIG. 6 shows schematic representation of a component structure made of several parts on a common carrier.

### DETAILED DESCRIPTION OF ILLUSTRATIVE EMBODIMENTS

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

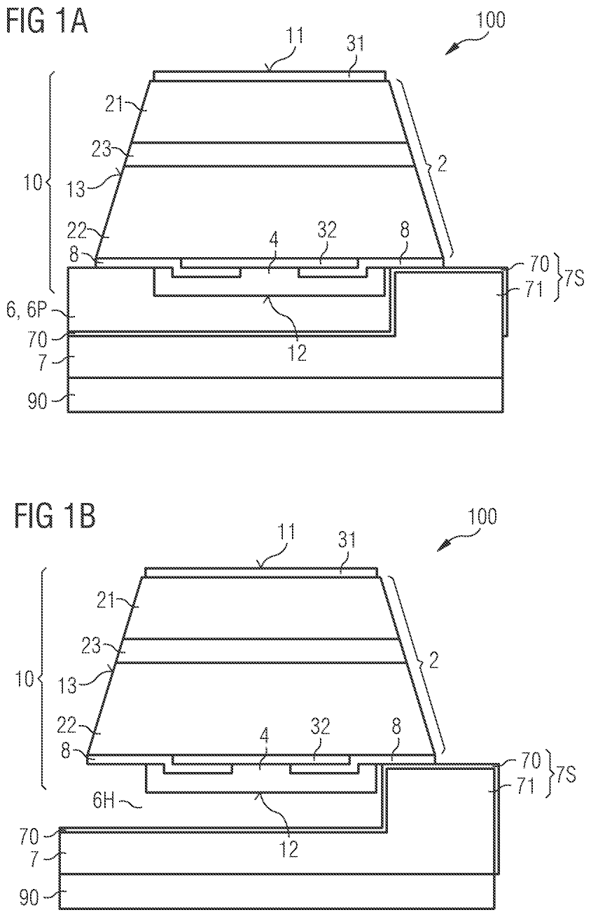

FIG. 1A shows a section of a component composite 100 in sectional view. The component composite 100 has an auxiliary carrier 90 and at least one component 10 or a plurality of components 10 arranged thereon. In the vertical direction, a sacrificial layer 6 is arranged between the auxiliary carrier 90 and the components 10. In particular, the sacrificial layer 6 directly adjoins the component 10 or directly adjoins the components 10.

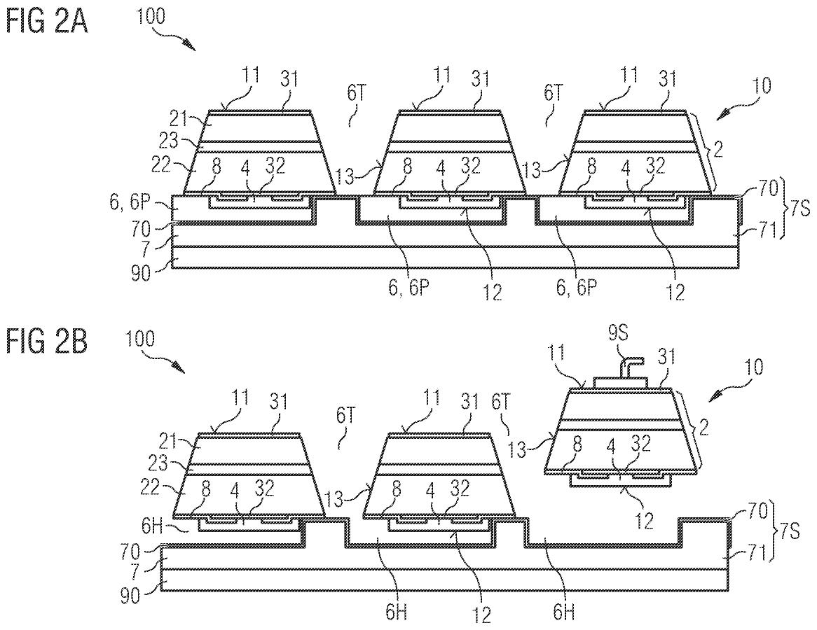

The component composite 100 comprises a retaining structure 7S which is arranged in the vertical direction in regions between the auxiliary carrier 90 and the sacrificial layer 6 and in regions between the auxiliary carrier 90 and the components 10. It is possible that the retaining structure 7S is directly adjacent to the sacrificial layer 6 and/or directly adjacent to the components 10. In FIG. 1A, only a component 10 and a partial layer 6P of the sacrificial layer 6 are shown schematically in the section of the component composite loo. In deviation from that, it is possible for the component composite 100 to comprise a plurality of components 10 and a plurality of partial layers 6P. Such a component composite 100 is schematically shown, for example, in FIG. 2A. The sacrificial layer 6 may be continuous or may comprise a plurality of laterally spaced partial layers 6P. In particular, the sacrificial layer 6 or the plurality of partial layers 6P is arranged in one recess or in multiple recesses of the retaining structure 7S.

The auxiliary carrier 90 may be a wafer substrate. In particular, the auxiliary carrier 90 is different from a growth substrate on which the components 10 are epitaxially grown. For example, the auxiliary carrier 90 is formed of an electrically conductive material, such as of a metal or a semiconductor material, in particular of a doped semiconductor material. In this case, it is possible that the auxiliary carrier 90 is electrically conductively connected to the component 10 or to the components 10 for instance via the electrically conductive retaining structure 7S and the electrically conductive sacrificial layer 6. Thus, as parts of the component composite 100, the components 10 can already be externally electrically contacted via the auxiliary carrier 90.

Alternatively, it is possible that the auxiliary carrier 90 is formed from an electrically insulating material or from a semiconductor material. In the component composite 100, the components 10 can be electrically contactable externally via the retaining structure 7S and/or via the sacrificial layer 6. If the retaining structure 7S is formed from an electrically insulating material, the electrically conductive sacrificial layer 6 can be formed to be freely accessible from the outside in places, so that the components 10 can be electrically contacted via the electrically conductive sacrificial layer 6.

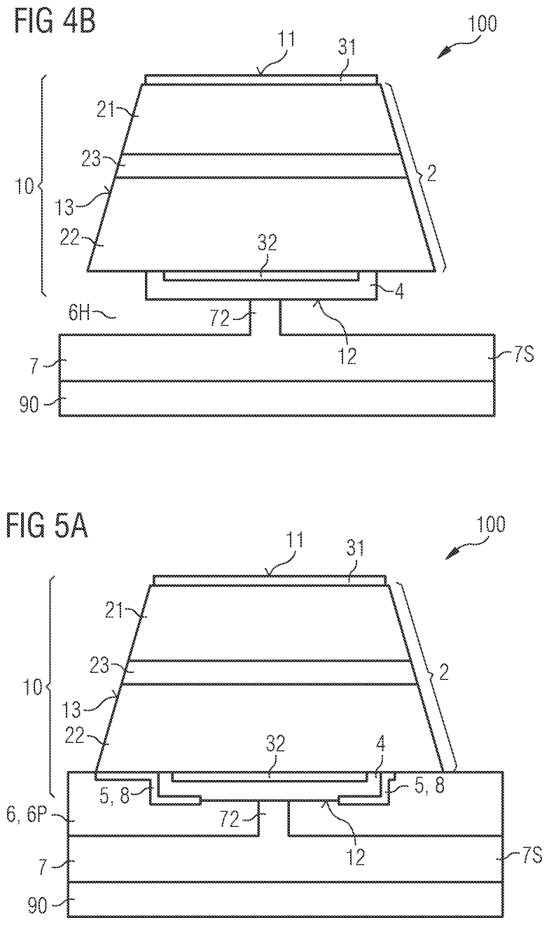

According to FIG. 1A, the retaining structure 7S has an anchoring layer 7. In particular, the anchoring layer 7 is directly adjacent to the auxiliary carrier 90. The anchoring layer 7 has local vertical elevations that form, for example, retaining elements 71 or 72 of the retaining structure 7S (see also FIG. 4A). Each component 10 may have a single retaining element 71 or 72 uniquely associated therewith. If a retaining element 71 or 72 is associated with a component 10, this component 10 may be mechanically fixed on the auxiliary carrier 90 by virtue of this retaining element 71 or 72 as long as a mechanical connection is maintained between the component 10 and the associated retaining element 71 or 72. It is possible that a plurality of retaining elements 71 and/or 72 are associated with each component 10. It is also possible that adjacent components 10, in particular exactly two, three or four adjacent components 10, are associated with a common, in particular single, retaining element 71. In FIG. 1A, the component 10 only partially covers the associated retaining element 71 in a top view of the auxiliary carrier 90. The retaining element 71 projects laterally beyond the component 10. In this sense, the retaining element 71 is formed as a tether.

In the absence of the sacrificial layer 6, the component 10 is preferably mechanically connected to the auxiliary carrier 90 exclusively via the retaining structure 7S. The retaining structure 7S serves as a connecting structure between the auxiliary carrier 90 and the components 10. The retaining structure 7S may be formed exclusively by the bonding layer 7 or exclusively by the bonding layer 7 and the passivation layer 70. In particular, the components 10 are in direct mechanical contact with the retaining structure 7S exclusively in the regions of the retaining elements 71 and/or 72. If the mechanical contact between the component 10 and the associated retaining element 71 or 72 is removed after the sacrificial layer 6 has been removed, the component 10 can be completely removed from the auxiliary carrier 9o.

The retaining elements 71 or 72 are formed in particular as integral parts of the anchoring layer 7. The retaining elements 71 or 72 and remaining areas of the anchoring layer 7 are in particular formed in one piece and/or from the same material. For example, the anchoring layer 7 with the retaining elements 71 and/or 72 is formed from an electrically conductive material, such as from a metal or from a transparent electrically conductive oxide (TCO). Alternatively, it is possible that the anchoring layer 7 comprising the retaining elements 71 and/or 72 is formed from an electrically insulating material, for instance from an electrically insulating oxide, plastic, adhesive, an epoxy, a thermoset such as benzocyclobutene, benzocyclobutene-based material, in particular a benzocyclobutene-based polymer.

According to FIG. 1A, the retaining structure 7S has a passivation layer 70 arranged in the vertical direction between the anchoring layer 7 and the sacrificial layer 6 or between the anchoring layer 7 and the components 10. In particular, the passivation layer 70 runs conformally to a surface of the anchoring layer 7 facing the components 10. The passivation layer 70 is in particular an atomic layer deposition layer, for example an oxide layer, such as an Al₂O₃ layer. Such a layer may be formed by atomic layer deposition and thus be particularly thin.

For example, the passivation layer 70 has a mean vertical layer thickness between a few nanometers and a few micrometers. For example, the mean vertical layer thickness of the passivation layer 70 is from 3 nm to 3 μm inclusive, in particular from 3 nm to 1 μm inclusive, from 3 nm to 300 nm inclusive, for instance from 10 nm to 100 nm inclusive. The anchoring layer 7 has a mean vertical layer thickness that is in particular at least three times, five times, ten times or at least one hundred times as great as the mean vertical layer thickness of the passivation layer 70. For example, a ratio of the mean vertical layer thickness of the anchoring layer 7 to the mean vertical layer thickness of the passivation layer 70 is from 3 to 1000, 10 to 1000, or from 10 to 100, inclusive. In deviation from the above, it is possible for the anchoring layer 7 to have a lower mean layer thickness than the passivation layer 70. In this case, the passivation layer may be a combination of PVD, CVD and/or ALD layers.

It is conceivable that the passivation layer 70 is electrically conductive or electrically insulating. In a plan view of the auxiliary carrier 90, the passivation layer 70 can partially or completely cover the anchoring layer 7. In particular, the passivation layer 70 directly adjoins the sacrificial layer 6 and/or directly adjoins the components 10.

If the retaining structure 7S comprises the passivation layer 70, the detachment of the components 10 from the auxiliary carrier 90 or from the anchoring layer 7 can be carried out in a simplified manner, since the passivation layer 70 is also arranged in particular between the retaining elements 71 and/or 72 and the components 10, and the components 10 can be separated or detached from the thin passivation layer 70 and thus from the retaining elements 71 and/or 72 in a simple manner, for example by using external force. If the retaining structure 7S has such a passivation layer 70, the auxiliary carrier 90 together with the anchoring layer 7 arranged thereon and the retaining elements 71 and/or 72 can be reused without great effort, for example already after removal of possible contamination. However, deviating from FIG. 1A and from FIGS. 1B to 3G, it is possible that the retaining structure 7S is free of such passivation layer 70. In this case, the anchoring layer 7, in particular with the retaining elements 71 and/or 72, can be directly adjacent to the sacrificial layer 6 and/or directly adjacent to the components 10.

The sacrificial layer 6 is preferably electrically conductive. In particular, the sacrificial layer 6 is based on silicon, germanium or molybdenum. The electrically conductive material of the sacrificial layer 6 may be of porous form. For example, the sacrificial layer 6 is a highly doped layer, in particular made of a semimetal, or of a highly doped semiconductor layer. In other words, the sacrificial layer may be formed of a semiconductor material or of a semimetal with additional use of dopants. For example, the sacrificial layer 6 is a highly doped Si-, Ge- or Mo-layer.

Preferably, the sacrificial layer 6 is formed to be removable from the component composite 100, in particular selectively removable. For example, the sacrificial layer 6 can be selectively removed from the component composite 100 by a chemical process, in particular by an etching process, without the layers of the components 10 or of the retaining structure 7S adjacent to the sacrificial layer 6 also being removed. SF6 or XeF2 may be used as the etchant. The layers adjacent to the sacrificial layer 6 may have a higher etch resistance than the sacrificial layer 6. For example, the passivation layer 70 or the anchoring layer 7 may be formed of a material that has a lower etch rate than a material of the sacrificial layer 6 with respect to an etchant such as SF6 or XeF2. The passivation layer 70 or the anchoring layer 7 may thus serve as an etch stop layer or a protective layer.

The component 10 may be an electrical component, in particular an optoelectronic component 10. For example, the component 10 is a light-emitting diode, in particular a μLED, i.e. an LED with geometric dimensions in the micrometer range, such as from 1 μm to 900 μm inclusive, from 10 μm to 600 μm inclusive, or from 30 μm to 300 μm inclusive, in particular from 1 μm to 100 μm, 1 μm to 30 μm, 1.5 μm to 10 μm, or from 1.5 μm to 8 μm inclusive.

According to FIG. 1A, the component 10 has a semiconductor body 2 comprising a first semiconductor layer 21, a second semiconductor layer 22 and an active zone 23 disposed between the first semiconductor layer 21 and the second semiconductor layer 22. The first semiconductor layer 21 faces away from the auxiliary carrier 90. The second semiconductor layer 22 faces the auxiliary carrier 9o. It is possible that the first semiconductor layer 21 is n-type and the second semiconductor layer 22 is p-type, or vice versa. Both the first semiconductor layer 21 and the second semiconductor layer 22 may be implemented as a single layer or as a sequence of layers.

An active zone 23 of the component 10 is understood to be an active zone in the semiconductor body 2 which is configured in particular for generating or detecting electromagnetic radiation. During operation of the component 10, the active zone 23 is configured to generate electromagnetic radiation for instance in the ultraviolet, visible or infrared spectral range. For example, the active zone 23 comprises a pn-junction or a collection of quantum structures configured to generate or detect electrical radiation.

The component 10 has a first electrical contact layer 31 and a second electrical contact layer 32. The contact layers 31 and 32 are assigned to different electrical polarities of the component 10. In particular, the first electrical contact layer 31 is configured for electrically contacting the first semiconductor layer 21. The first contact layer 31 may be formed of a transparent electrically conductive oxide, such as indium tin oxide (ITO). It is also possible that the contact layer 31 comprises Au and/or Ge. The second electrical contact layer 32 is configured for electrically contacting the second semiconductor layer 22 and may be formed of a metal or of a transparent electrically conductive oxide.

The first contact layer 31 is arranged on a front side of the semiconductor body 2 and is in particular freely accessible from the outside. The second contact layer 32 is arranged on a rear side of the semiconductor body 2 and is in particular not freely accessible from the outside. The component 10 has a connection layer 4 via which the second contact layer 32 can be electrically contacted externally. The connection layer 4 can be formed from an electrically conductive material, for example from a transparent electrically conductive oxide, for example from indium tin oxide (ITO), or from a metal such as aluminum, silver, titanium, rhodium, chromium, gold or platinum.

The component 10 has an insulating layer 8 which is arranged in regions between the connection layer 4 and the second contact layer 32. The insulating layer 8 is formed, for example, from an electrically insulating oxide or nitride, such as SiO₂. Since the second contact layer 32 covers the semiconductor body 2 only in regions, the insulating layer 8 can cover, in particular completely cover, regions of a rear surface of the semiconductor body 2 that are not covered by the second contact layer 32. The insulating layer 8 has an opening through which the connection layer 4 extends to the second contact layer 32. In particular, the insulating layer 8 directly adjoins the sacrificial layer 6, the semiconductor body 2, the second contact layer 32, the connection layer 4 and/or directly adjoins the retaining structure 7S. In FIG. 1A, the insulating layer 8 is directly adjacent to the passivation layer 70 of the retaining structure 7S.

The connection layer 4 may be in direct or indirect electrical contact with the second contact layer 32. In particular, the connection layer 4 is covered and/or surrounded by the sacrificial layer 6 such that the connection layer 4 is not freely accessible from the outside in the presence of the sacrificial layer 6. However, the connection layer 4 is electrically conductively connected to the sacrificial layer 6 so that the connection layer 4 and thus the second contact layer 32 can be electrically contacted externally via the electrically conductive sacrificial layer 6.

For example, the sacrificial layer 6 is freely accessible from the outside in places. It is also possible that the electrical contact to the sacrificial layer 6 is led out laterally to an edge region of the auxiliary carrier 90 or to the anchoring layer 7, for example via a conductor track or via a metallic reinforcement. In this case, the auxiliary carrier may be formed of an electrically insulating material or of a poorly conducting material such as glass or sapphire, or of a semiconductor material such as Si or Ge.

Furthermore, it is possible for the external electrical contacting of the sacrificial layer 6 to be made throughout the anchoring layer 7 or throughout the auxiliary carrier 90. For this purpose, vias may be formed extending throughout the anchoring layer 7 and the auxiliary carrier 90. As an alternative, the anchoring layer 7 and/or the auxiliary carrier 90 may/can be electrically conductive. For example, the anchoring layer 7 is formed from an electrically conductive oxide. The auxiliary carrier 90 may be formed from a semimetal or from a metallic material or from a semiconductor material, in particular from doped semiconductor material.

The component 10 has a front side ii and a rear side 12. In particular, the component 10 is spatially bounded along the vertical direction by the front side ii and by the rear side 12. In other words, the front side ii and the rear side 12 define outer limits of the spatial extent of the component 10 along the vertical direction.

The component 10 has side surfaces 13 that are formed, in particular, at an oblique angle. For example, the side surfaces 13 form with the main extension surface of the first contact layer 31 or with the front side 11 an internal obtuse angle which is, for example, between 95° and 135° inclusive, for instance between 95° and 120° inclusive. The side surfaces 13 of the component 10 may be formed mainly by side surfaces of the semiconductor body 2. In sectional view, the semiconductor body 2 has the shape in particular of a trapezoid. Deviating from FIG. 1A, it is possible that the side surfaces 13 form a substantially perpendicular angle or an inner acute angle with the main extension surface of the first contact layer 31 or with the front side ii. The side surfaces 13 may be covered by in particular an electrically insulating protective layer. Deviating from FIG. 1A, it is possible that the side surfaces 13 form with the main extension surface of the first contact layer 31 or with the front side 11 an internal acute angle which is, for example, between 45° and 85° inclusive, for instance between 60° and 85° inclusive.

According to FIG. 1A, the front side ii of the component 10 is defined, at least places, by an exposed surface of the first contact layer 31. The rear side 12 of the component 10 is defined in places by a surface of the connection layer 4 which faces the sacrificial layer 6 or the auxiliary carrier 90, and in places by a surface of the insulating layer 8 which faces the sacrificial layer 6 or the auxiliary carrier 90. According to FIG. 1A, the component 10 thus directly adjoins the sacrificial layer 6 and directly adjoins the retaining structure 7S.

The exemplary embodiment of a component composite 100 shown in FIG. 1B basically corresponds to the exemplary embodiment shown in FIG. 1A. In contrast, the sacrificial layer 6 has been removed. Instead of the sacrificial layer 6 or of the partial layer 6P of the sacrificial layer 6, there is a cavity 6H between the component 10 and the retaining structure 7S or between the component 10 and the auxiliary carrier 90, respectively. In particular, the connection layer 4 is directly adjacent to the cavity 6H, with the connection layer 4 being spatially spaced from the retaining structure 7S. The rear side 12 of the respective component 10 further directly adjoins the retaining structure 7S, in particular the retaining element 71 or 72, in places. Due to the adhesion to the retaining elements 71 or 72, the components 10 continue to remain orderly on the auxiliary carrier 90, even after the sacrificial layer 6 has been partially or completely removed.

For example, at least 0.1%, 0.3%, 0.6%, 1%, 3%, 5% or 10% and at most 30%, 25% or 20%, 10%, 5%, 1% of the total area of the respective rear side 12 adhere to the retaining element or elements 71 and/or 72. For example, a proportion of the area of the retaining elements 71 and/or 72 is between 0.1% and 5% inclusive, between 0.1% and 1% inclusive, for instance between 0.4% and 0.6% inclusive. It is possible that at least 70%, 75%, 80%, 90%, 95% or 99% of the total area of the respective rear side 12 is directly adjacent to the cavity 6H. After removal of the sacrificial layer 6, the components 10 are mechanically connected to the auxiliary carrier 90 in particular exclusively via the retaining structure 7S. In a subsequent method step, the components 10 can be separated individually or in groups from the retaining structure 7S and thus from the auxiliary carrier 90. For this purpose, the mechanical connection between the component 10 and the associated retaining element 71 or 72 are detachable. The detachment takes place in particular at a common interface between the component 10 and the retaining structure 7S, for example at a common interface between the insulating layer 8 and the passivation layer 70 or at a common interface between the insulating layer 8 and the anchoring layer 7. Deviating from this, it is possible that the component composite boo is free of a retaining structure 7S.

The insulating layer 8, the passivation layer 70 and/or the anchoring layer 7 can be formed as separate layers, in particular from different materials. This facilitates the detachment of the components 10 from the retaining structure 7S. It is possible that the detached components 10 are free of residues or traces of the retaining structure 7S. However, it is also conceivable that the detached components 10 have residues and/or traces of the retaining structure 7S or the retaining elements 72 or 72, in particular on the rear sides 12. Alternatively, the insulating layer 8, the passivation layer 70 and/or the anchoring layer 7 may be formed from the same material. For example, the retaining structure 7S is formed from a combination of SiO₂ layers or TCO layers, with the SiO₂ layers or the TCO layers being deposited on top of each other. The TCO layers may be indium tin oxide layers.

The exemplary embodiment of a component composite 100 shown in FIG. 2A corresponds to the exemplary embodiment shown in FIG. 1A. In contrast, FIG. 2A schematically illustrates a plurality of components 10 rather than a single component 10. The components 10 may be arranged in a matrix-like manner, i.e., in rows and columns, on the auxiliary carrier 90. The components 10 may be of different or same construction. The components 10 are of the same construction if, for example, they have the same structural configuration. In particular, the semiconductor bodies 2 of the components 10 may have the same type of structure. For example, the semiconductor bodies 2 have the same diode structure. The semiconductor bodies 2 may be based on the same semiconductor compound material. It is also possible that the semiconductor bodies 2 or the components 10 are produced by common production steps.

According to FIG. 2A, each component 10 may be assigned to a partial layer 6P of the sacrificial layer 6. According to FIG. 2A, the components 10 or the semiconductor bodies 2 are laterally spaced from each other by separation trenches 6T. In the separation trenches 6T, the partial layers 6P of the sacrificial layer 6 are freely accessible, in particular in places. At these regions, the partial layers 6P can be electrically contacted externally. The components 10 can thus already be electrically contacted in a targeted and selective manner in the component composite 100, i.e. at wafer level, via the electrically conductive sacrificial layer 6 and the first contact layers 31. An etchant can be applied to the freely accessible regions of the sacrificial layer 6 for under-etching or removing the sacrificial layer 6, in particular after the components lo have been probed or electro-optically characterized.

The exemplary embodiment of a component composite 100 shown in FIG. 2B corresponds to the exemplary embodiment shown in FIG. 2A after the sacrificial layer 6 has been removed. In particular, the removal of the sacrificial layer 6 is performed only after probing or only after electro-optical characterizing the components 10. FIG. 2B schematically shows how a component 10 can be removed by a stamp 9S and thus selectively detached from the retaining structure 7S or from the auxiliary carrier 90. It is possible that a plurality of stamps 9S are used to transfer a plurality of components 10 simultaneously. The components 10 that are transferred may be those components 10 that meet the technical requirements, or those components 10 that do not meet the predetermined technical requirements and are thus discarded.

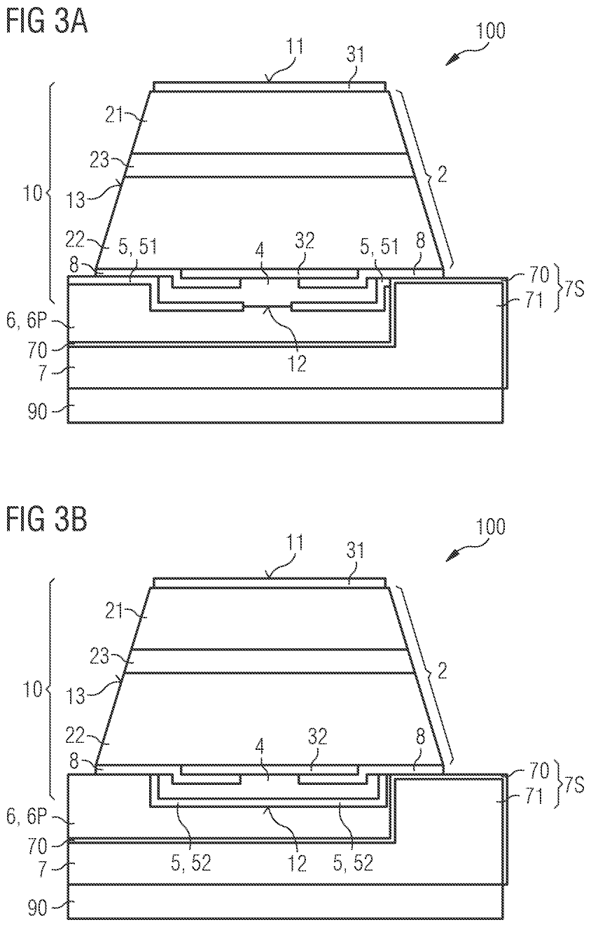

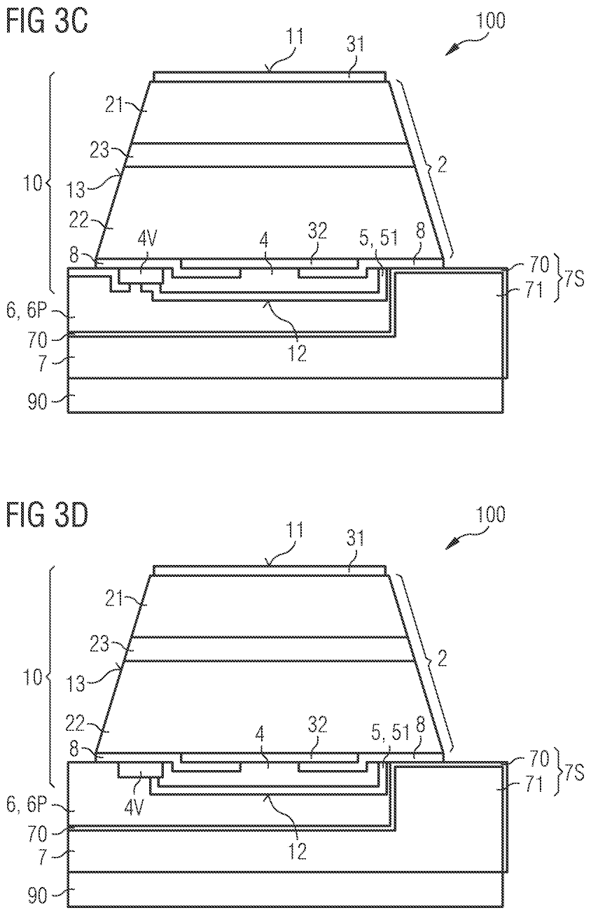

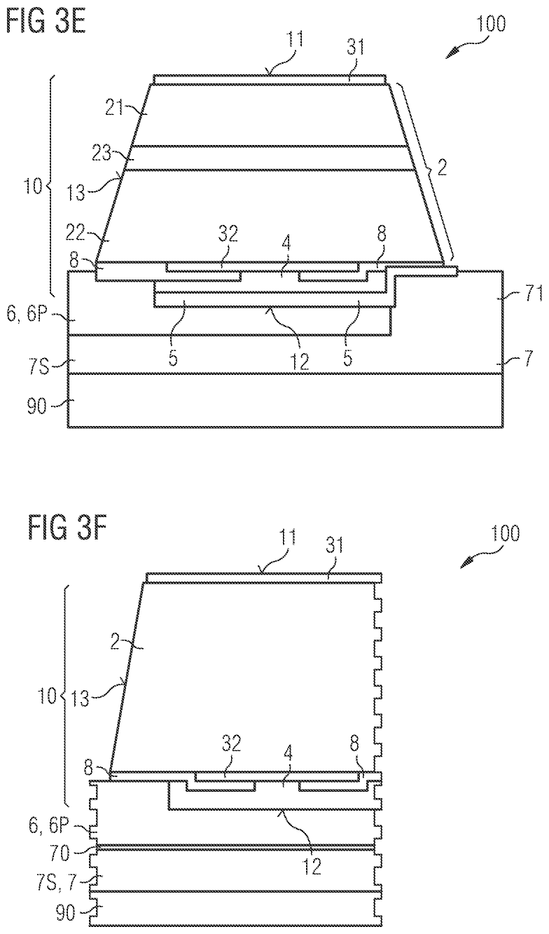

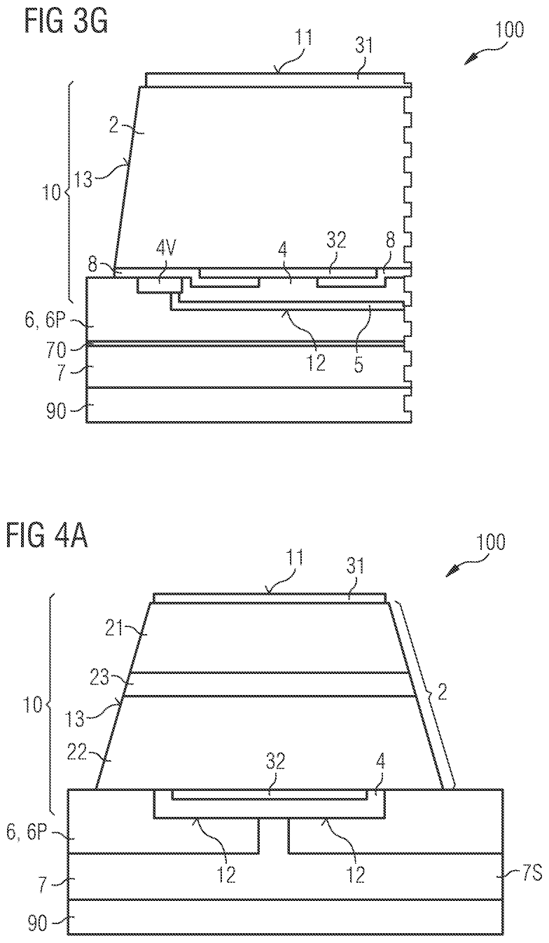

The exemplary embodiment of a component composite 100 shown in FIG. 3A basically corresponds to the exemplary embodiment shown in FIG. 1A. In contrast thereto, the component 10 has a boundary layer 5 which covers the connection layer 4 and the insulating layer 8 at least in places. The rear side 12 of the component 10 is formed in regions by a surface of the boundary layer 5. In particular, the boundary layer 5 is directly adjacent to the insulating layer 8, to the connection layer 4 and/or directly adjacent to the sacrificial layer 6. Preferably, the boundary layer 5 is formed as a diffusion barrier layer. Due to the presence of the boundary layer 5, migration of particles between the connection layer 4 and the sacrificial layer 6 or between the sacrificial layer 6 and the semiconductor body 2 can be prevented or reduced.

According to FIG. 3A, the boundary layer 5 is formed as an electrically insulating boundary layer 51, which is formed, for example, from a nitride material, such as SiN. The boundary layer 51 and the insulating layer 8 can be formed from different materials. The electrically insulating boundary layer 51 only partially covers the connection layer 4 and has an opening in which the connection layer 4 is in particular in direct electrical and mechanical contact with the sacrificial layer 6.

The exemplary embodiment of a component composite 100 shown in FIG. 3B basically corresponds to the exemplary embodiment shown in FIG. 3A. In contrast, the boundary layer 5 or the diffusion barrier layer is formed as an electrically conductive boundary layer 52. The electrically conductive boundary layer 52 may completely cover the connection layer 4. For example, the boundary layer 52 is formed of a metal, such as chromium or titanium.

The exemplary embodiment of a component composite 100 shown in FIG. 3C basically corresponds to the exemplary embodiment shown in FIG. 3A. In contrast, the boundary layer 5 completely covers the connection layer 4. For electrically contacting the connection layer 4 to the sacrificial layer 6, the component 10 has a bonding layer 4V which is covered only in places by the electrically insulating boundary layer 51. The bonding layer 4V is arranged laterally to the connection layer 4 and may be directly adjacent thereto. The bonding layer 4V may be formed from an electrically conductive material that is different from the material of the connection layer 4. For example, the connection layer 4 is formed of gold. The bonding layer 4V may be formed from a metal other than gold, such as chromium or titanium. Referring to FIG. 3C, the electrically insulating boundary layer 51 has an opening in which the bonding layer 4V is in direct electrical contact with sacrificial layer 6.

The exemplary embodiment of a component composite 100 shown in FIG. 3D basically corresponds to the exemplary embodiment shown in FIG. 3C. In contrast, the electrically insulating boundary layer 51 does not have an opening. A side surface of the bonding layer 4V is not covered by the electrically insulating boundary layer 51 and is in direct electrical contact with the sacrificial layer 6. A further surface of the bonding layer 4V facing the sacrificial layer 6 is also only partially covered by the boundary layer 51 and is in direct electrical contact with the sacrificial layer 6. The bonding layer 4V can also serve as a diffusion barrier layer. According to FIG. 3D, the component 10 comprises the boundary layer 51 as an electrically insulating diffusion barrier layer and the bonding layer 4V as an electrically conductive diffusion barrier layer.

The exemplary embodiment of a component composite 100 shown in FIG. 3E basically corresponds to the exemplary embodiment shown in FIG. 3A. In contrast, the component composite 100 or the component 10 is free of the passivation layer 70, in particular free of an ALD layer. The boundary layer 5 covers a rear side of the connection layer 4, in particular completely. The boundary layer 5 may be electrically insulating. For example, the boundary layer 5 is an electrically insulating oxide layer, such as a SiO₂ or a nitride layer. The boundary layer 5 can be formed as an electrically insulating diffusion barrier layer which prevents or reduces migration of particles from the Si-, Mo- or Ge-sacrificial layer 6 into the connection layer 4, in particular into the Au-connection layer 4.

According to the exemplary embodiments shown in FIGS. 1A to 3D, the component composite 100 has a gap below each component 10 that is filled by the sacrificial layer 6. This gap is located in particular in the lateral direction between the connection layer 4 and the retaining element 71, in particular between the boundary layer 5 and the retaining element 71. If the sacrificial layer 6 is removed, the cavity 6H has a gap in particular filled with air at this location. Through the gap, the connection layer 4 or the boundary layer 5 is laterally spaced from the retaining element 71 or from the passivation layer 70. This exemplary embodiment allows the component 10 to be detached safely and in a simplified manner, since ideally only the insulating layer 8 is adjacent to the retaining element 71 or to the passivation layer 70.

According to FIG. 3E, the gap may be completely filled by the boundary layer 5. In other words, there is no material of the sacrificial layer 6 in the gap. In particular, the boundary layer 5 is directly adjacent to the anchoring layer 7 in places. In the absence of the sacrificial layer 6, mechanical adhesion between the component 10 and the retaining structure 7S occurs in particular exclusively at a common interface between the boundary layer 5 and the anchoring layer 7 or between the boundary layer 5 and the retaining element 71.

Deviating from FIGS. 1A to 3E, it is possible that several adjacent components 10, in particular exactly two or four adjacent components 10, are assigned to a common retaining element 71. In a plan view, the adjacent components 10 may have overlaps with the same retaining element 71. Such an exemplary embodiment of the component composite 100 may be provided by an additional mirroring of the exemplary embodiment shown, for example, in FIG. 3A, 3B, 3C, 3D or 3E, so that the retaining elements 71 of two components 10 coincide or form a common retaining element 71. The adjacent components 10 can thus be assigned to a common, in particular single, retaining element 71. The adjacent components 10 can be held either from the left or from the right on the auxiliary carrier 90. This offers advantages in processing, in particular for particularly small components 10 with a small distance from each other.

In all exemplary embodiments described so far, the anchoring layer 7 may be electrically insulating. In particular, the anchoring layer 7 is based on benzocyclobutene (BCB) or is formed from this material. Alternatively, the anchoring layer 7 may be formed from an electrically insulating adhesive, epoxies, thermosets, a transparent electrically conductive oxide, or a metal. The auxiliary carrier 90 may be electrically conductive and formed of a metal. The components 10 can be electrically contacted externally on the rear side via the auxiliary carrier 90 or via the anchoring layer 7.

The exemplary embodiments of a component composite 100 shown in FIG.s 3F and 3G substantially correspond to the exemplary embodiments shown in FIGS. 1A and 3D, respectively. In contrast, only sections without the retaining elements 71 are shown. This is to clarify that the exemplary embodiments shown in FIGS. 1A to 3E are not necessarily limited to the retaining structure 7S with the retaining elements 71. In contrast to FIGS. 1A to 3E, alternatively or in addition to the retaining elements 71, the retaining structure 7S may have other forms of retaining elements.

Another form of retaining elements of the retaining structure 7S is schematically shown in FIG. 4A. The exemplary embodiment of a component composite 100 shown in FIG. 4A basically corresponds to the exemplary embodiment shown in FIG. 1A. According to FIG. 4A, the retaining structure 7S has at least one retaining element 72 for each component 10, in particular in the form of a retaining column. In a top view of the auxiliary carrier 90, the component 10 completely covers the associated retaining element 72. Deviating from FIG. 4A, for each component 10, it is possible that the retaining structure 7S has a plurality of such retaining elements 72, for example at least two, three or at least four such column-like retaining elements 72.

As further differences to FIG. 1A, the component 10 illustrated in FIG. 4A is free of an insulating layer 8 and free of a passivation layer 70. Furthermore, the second contact layer 32 is surrounded by the connection layer 4 in lateral directions. However, it is possible that the component 10 illustrated in FIG. 4A has such an insulating layer 8 and/or such a passivation layer 70.

The exemplary embodiment shown in FIG. 4B corresponds to the exemplary embodiment of a component composite 100 after removal of the sacrificial layer 6 shown in FIG. 4A.

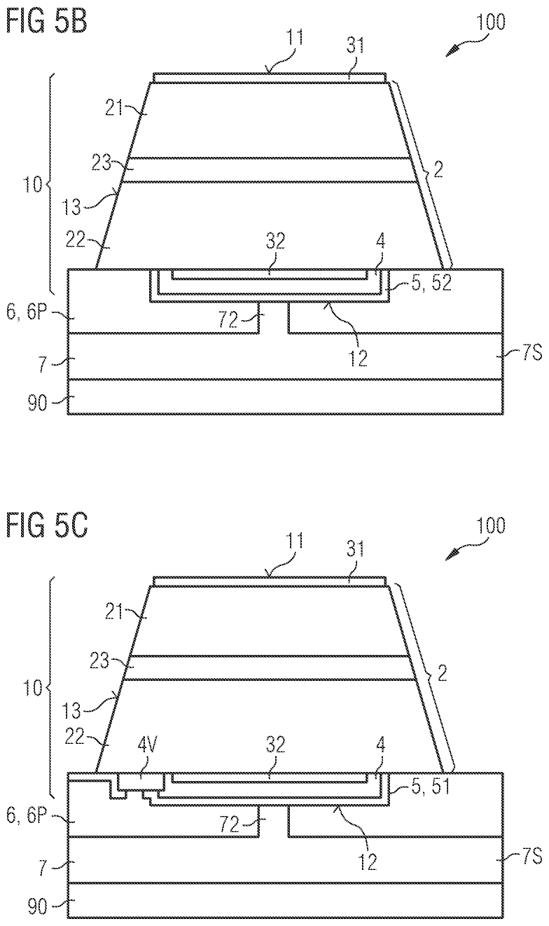

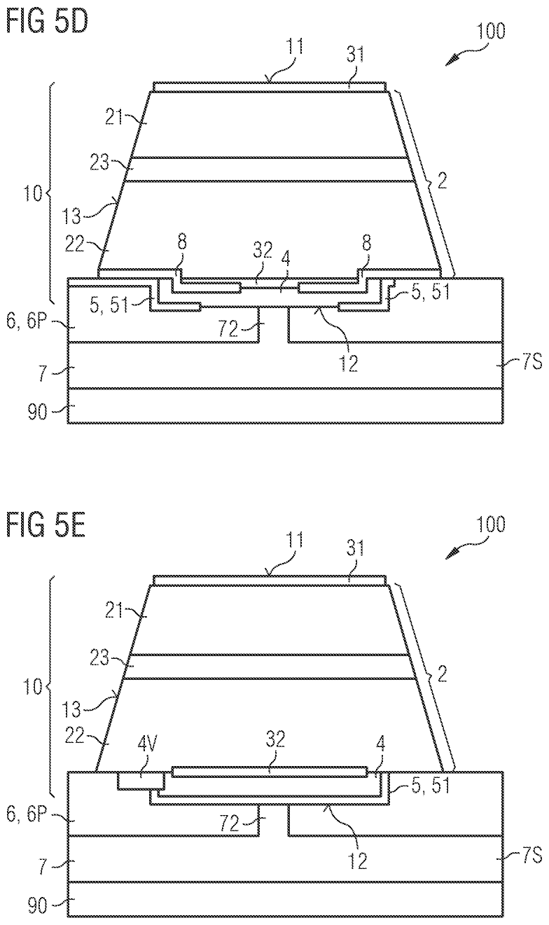

The exemplary embodiment of a component composite 100 shown in FIG. 5A is substantially the same as the exemplary embodiment shown in FIG. 4A, but with an insulating layer 8 or with a boundary layer 5, respectively. The insulating layer 8 or the boundary layer 5 shown in FIG. 5A may be formed analogously to the insulating layer 8 or to the boundary layer 5 according to the previous exemplary embodiments described herein. For example, the boundary layer 5 shown in FIG. 5A is formed as an electrically insulating diffusion barrier layer.

The exemplary embodiment shown in FIG. 5B basically corresponds to the exemplary embodiment shown in FIG. 5A. In contrast, the boundary layer 5 is formed as an electrically conductive diffusion barrier layer, analogously to the example shown in FIG. 3B.

The exemplary embodiment shown in FIG. 5C basically corresponds to the exemplary embodiment shown in FIG. 5B. In contrast, the boundary layer 5 or 51 is formed as an electrically insulating diffusion barrier layer. For electrically contacting the connection layer 4, the component 10 has a bonding layer 4V analogously to the exemplary embodiment shown in FIG. 3C. The features described in connection with FIG. 3C, in particular with respect to the bonding layer 4V and the boundary layer 51, can therefore also be used for the exemplary embodiment shown in FIG. 5C.

The exemplary embodiment shown in FIG. 5D basically corresponds to the exemplary embodiment shown in FIG. 4A, but with the insulating layer 8 and the boundary layer 5 or 51. The design of the insulating layer 8 and/or the boundary layer 51 according to FIG. 5D corresponds to the design of the insulating layer 8 and/or the boundary layer 51 according to FIG. 3A. The features described in connection with FIG. 3A, in particular with regard to the insulating layer 8 and the boundary layer 51, can therefore also be used for the exemplary embodiment shown in FIG. 5D.

The exemplary embodiment shown in FIG. 5E basically corresponds to the exemplary embodiment shown in FIG. 5C, however, with the bonding layer 4V and with the boundary layer 51 in particular according to FIG. 3D. The features described in connection with FIG. 3D, in particular with respect to the bonding layer 4V and the boundary layer 51, can therefore also be used for the exemplary embodiment illustrated in FIG. 5E.

The exemplary embodiment shown in FIG. 5F basically corresponds to the exemplary embodiment shown in FIG. 5A but with the boundary layer 5 in particular according to FIG. 3E. The features described in connection with FIG. 3E, in particular with respect to the anchoring layer 7 and the auxiliary carrier, can therefore also be used for the exemplary embodiment illustrated in FIG. 5F.

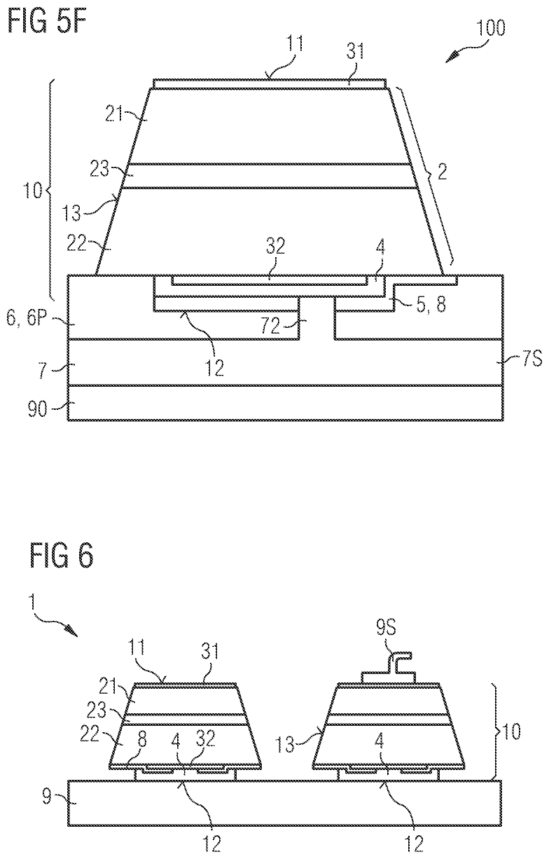

FIG. 6 shows a component structure 1. The component structure 1 has a carrier 9, in particular a common carrier 9, on which the components 10 are arranged and fixed individually or in groups. The component structure 1 may be part of an electronic device. For example, the electronic device is a smartphone, touchpad, laser printer, video wall, display, recognition camera or system of LEDs, sensors, laser diodes and/or detectors, automotive lighting, headlights, brake lights, displays in/on vehicles. The component 10 or the component structure 1 may further find application in a light source. For example, the component 10 or component structure 1 is for general lighting, such as interior or exterior lighting. Furthermore, the component 10 or the component structure 1 may be implemented as a light source for a headlight, such as a motor vehicle headlight.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

1.-18. (canceled)

19. A component composite comprising:
an auxiliary carrier;
a plurality of components;
a retaining structure; and
an electrically conductive sacrificial layer,
wherein each of the components has a connection layer which faces the sacrificial layer and is electrically conductively connected to the sacrificial layer,
wherein the sacrificial layer is arranged in vertical direction between the auxiliary carrier and the components, and
wherein the sacrificial layer is to be removable and the components are mechanically connected to the auxiliary carrier only via the retaining structure in addition to the sacrificial layer.

20. The component composite according to claim 19, wherein the components are laterally spaced from one another by separation trenches and the sacrificial layer is freely accessible in regions in the separation trenches.

21. The component composite according to claim 19, wherein for each component the retaining structure has a vertically projecting retaining element which—in plan view of the auxiliary carrier—is completely covered by the associated component.

22. The component composite according to claim 19, wherein for each component, the retaining structure has a vertically projecting retaining element which, in plan view of the auxiliary carrier, is arranged in regions below and in regions to a side of the associated component.

23. The component composite according to claim 19, wherein the components are to be transferable in that, after removal of the sacrificial layer, the components are mechanically connected to the auxiliary carrier exclusively via the retaining structure and are detachable from the retaining structure and thus from the auxiliary carrier.

24. The component composite according to claim 19, wherein the retaining structure is an anchoring layer formed of a metal, an electrically conductive oxide, an electrically insulating material, an epoxy, a thermoset, or a benzocyclobutene-based material.

25. The component composite according to claim 24, wherein the retaining structure has an atomic layer deposition layer as a passivation layer which is arranged on the anchoring layer.

26. The component composite according to claim 19,
wherein each of the components comprises a front-side contact layer and a rear-side contact layer,
wherein the front-side contact layer and the rear-side contact layer are assigned to different electrical polarities of the associated component,
wherein the rear-side contact layer is electrically conductively connected to the associated connection layer, and
wherein the front-side contact layer is freely accessible.

27. The component composite according to claim 19, wherein the connection layer is in direct physical and electrical contact with the sacrificial layer.

28. The component composite according to claim 19, wherein the connection layer is covered by an electrically insulating boundary layer, and wherein the boundary layer is arranged between the connection layer and the sacrificial layer and has an opening in which the connection layer is in direct electrical contact with the sacrificial layer.

29. The component composite according to claim 19,
wherein in plan view, the connection layer is completely covered by an electrically insulating boundary layer,
wherein the boundary layer is arranged between the connection layer and the sacrificial layer, and
wherein an electrically conductive bonding layer is laterally adjacent to the connection layer, is at least partially non-covered by the boundary layer, and thus electrically conductively connects the connection layer to the sacrificial layer.

30. The component composite according to claim 19, wherein the connection layer is completely covered by an electrically conductive boundary layer, and wherein the electrically conductive boundary layer is directly adjacent to the connection layer and directly adjacent to the sacrificial layer.

31. The component composite according to claim 19, wherein the sacrificial layer is a doped Si-, Ge- or Mo-layer.

32. The component composite according to claim 19, wherein the connection layer is a metal layer.

33. The component composite according to claim 19, wherein the connection layer is formed from a transparent electrically conductive material.

34. The component composite according to claim 19, wherein the components are optoelectronic components or micro-LEDs.

35. A method for producing or probing components at wafer level, the method comprising:
providing a component composite with an auxiliary carrier, a plurality of components and an electrically conductive sacrificial layer, wherein each of the components has a connection layer which faces the sacrificial layer and is electrically conductively connected to the sacrificial layer, wherein the sacrificial layer is arranged in vertical direction between the auxiliary carrier and the components, and wherein the sacrificial layer is formed to be removable; and
probing the components, wherein the auxiliary carrier is a wafer substrate, and wherein the components are electrically connected via the sacrificial layer while the components remain mechanically connected to the auxiliary carrier; or
removing the sacrificial layer to form cavities between the auxiliary carrier and the components, wherein the components are mechanically connected to the auxiliary carrier only via a retaining structure, and wherein the retaining structure is arranged in the vertical direction between the auxiliary carrier and the components, and selectively separating the components from the auxiliary carrier to produce the components by selectively separating or detaching the respective components from the retaining structure.

36. The method according to claim 35, further comprising:
fixing the component composite to a further auxiliary carrier, wherein the components are arranged between the auxiliary carrier and the further auxiliary carrier;
removing the auxiliary carrier so that the components are mechanically supported only by the further auxiliary carrier; and
separating the components from the further auxiliary carrier.

37. A component composite comprising:
an auxiliary carrier;
a plurality of components;
a retaining structure; and
an electrically conductive sacrificial layer,
wherein each of the components has a connection layer which faces the sacrificial layer and is electrically conductively connected to the sacrificial layer,
wherein the sacrificial layer is arranged in vertical direction between the auxiliary carrier and the components,
wherein the sacrificial layer is formed to be removable and the components are mechanically connected to the auxiliary carrier only via the retaining structure in addition to the sacrificial layer,
wherein, in plan view, the connection layer is completely covered by an electrically insulating boundary layer,
wherein the boundary layer is arranged between the connection layer and the sacrificial layer, and
wherein an electrically conductive bonding layer is laterally adjacent to the connection layer, is at least partially non-covered by the boundary layer and thus electrically conductively connects the connection layer to the sacrificial layer.
